(19) United States
(12) Patent Application Publication
(10) Pub. No.: US 2013/0186145 A1
(43) Pub. Date: Jul. 25, 2013

(54) LASER ANNEALING APPARATUS

(71) Applicants: Atsushi NAKAMURA, Kanazawa-shi (JP); Shigeki TERADA, Kitamoto-shi (JP)

(72) Inventors: Atsushi NAKAMURA, Kanazawa-shi (JP); Shigeki TERADA, Kitamoto-shi (JP)

(21) Appl. No.: 13/747,789

(22) Filed: Jan. 23, 2013

(30) Foreign Application Priority Data
Jan. 23, 2012 (JP) 2012-011403

(51) Int. Cl. H01L 21/02

(52) U.S. Cl. CPC H01L 21/02686
USPC 65/355

(57) ABSTRACT

According to one embodiment, a laser annealing apparatus includes a laser device configured to emit a pulse laser beam, an anneal chamber including a stage on which a process substrate, on which an amorphous silicon thin film is formed, is placed, an optical module disposed between the laser device and the anneal chamber and configured to guide the pulse laser beam, which is emitted from the laser device, to the anneal chamber, a platform frame on which the laser device, the anneal chamber and the optical module are mounted, and an elastic body configured to lift the platform frame from a building floor.

### CROSS-REFERENCE TO RELATED APPLICATIONS

This application is based upon and claims the benefit of priority from Japanese Patent Application No. 2012-011403, filed Jan. 23, 2012, the entire contents of which are incorporated herein by reference.

### FIELD

Embodiments described herein relate generally to a laser annealing apparatus.

### BACKGROUND

Flat-panel display devices, such as liquid crystal display devices and electroluminescence display devices, have been used in various fields by virtue of their features. In such flat-panel display devices, a thin-film transistor (TFT) including a polysilicon semiconductor layer has begun to be used as a switching element of each of pixels.

This polysilicon semiconductor layer can be formed by an excimer laser annealing (ELA) method in which a laser beam is radiated in a pulsating form from an excimer laser device to amorphous silicon which is formed on an insulative substrate. In the excimer laser annealing method, it is required to stably form polysilicon over the entire area.

The scale of the whole laser annealing apparatus has been increasing, as large-sized substrates have been applied for mass-production of flat-panel display devices. Thus, the countermeasure against vibrations of the apparatus is very important.

### BRIEF DESCRIPTION OF THE DRAWINGS

FIG. 1 schematically illustrates the structure of a laser annealing apparatus according to an embodiment.

FIG. 2 schematically illustrates an example of a platform frame which is applicable to the laser annealing apparatus shown in FIG. 1.

FIG. 3 schematically illustrates another example of the platform frame which is applicable to the laser annealing apparatus shown in FIG. 1.

FIG. 4 schematically illustrates the structure of a laser annealing apparatus according to a comparative example.

### DETAILED DESCRIPTION

In general, according to one embodiment, a laser annealing apparatus includes a laser device configured to emit a pulse laser beam; an anneal chamber including a stage on which a process substrate, on which an amorphous silicon thin film is formed, is placed; an optical module disposed between the laser device and the anneal chamber and configured to guide the pulse laser beam, which is emitted from the laser device, to the anneal chamber; a platform frame on which the laser device, the anneal chamber and the optical module are mounted; and an elastic body configured to lift the platform frame from a building floor.

Embodiments will now be described in detail with reference to the accompanying drawings. In the drawings, structural elements having the same or similar functions are denoted by like reference numerals, and an overlapping description is omitted.

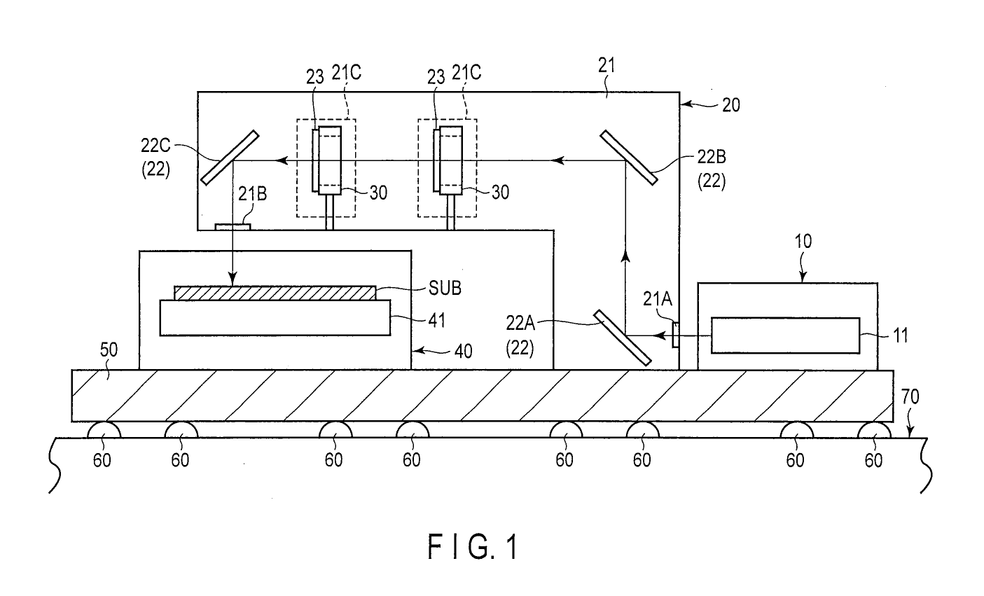

FIG. 1 schematically illustrates the structure of a laser annealing apparatus according to an embodiment.

Specifically, the laser annealing apparatus includes a laser device 10, an optical module 20, an anneal chamber 40, a platform frame 50, and an elastic body 60.

The laser device 10 includes an excimer laser oscillator 11 which emits a pulse laser beam with an ultraviolet wavelength. The anneal chamber 40 includes a stage 41 on which a process substrate SUB, on which an amorphous silicon thin film is formed, is placed. The stage 41 is movable in two mutually perpendicular directions or in a rotational direction in a plane which is parallel to the process substrate SUB. The optical module 20 is disposed between the laser device 10 and the anneal chamber 40, and guides a pulse laser beam, which is emitted from the laser device 10, to the anneal chamber 40. The optical module 20 includes a housing 21, a plurality of reflection mirrors 22, a plurality of lenses 23, and lens holders 30.

The housing 21 is formed in a cylindrical shape surrounding an optical path between the laser device 10 and the anneal chamber 40. A first window 21A, which takes in a pulse laser beam emitted from the laser device 10, is provided on that side of the housing 21, which is opposed to the laser device 10. A second window 21B, which emits the laser beam toward the anneal chamber 40, is provided on that side of the housing 21, which is opposed to the anneal chamber 40. In addition, doors 21C, which are located on lateral sides of the lens holders 30, are provided on a lateral side of the housing 21.

The reflection mirrors 22 mainly guide the pulse laser beam, which is emitted from the laser device 10, to the anneal chamber 40, and are fixed in the housing 21. The reflection mirrors 22 include, for example, a reflection mirror 22A configured to upwardly reflect the pulse laser beam which is taken in from the first window 21A, a reflection mirror 22B configured to deflect the optical path of the pulse laser beam reflected by the reflection mirror 22A, and a reflection mirror 22C configured to reflect the pulse laser beam, which has been reflected by the reflection mirror 22B, downward to the second window 21B. Incidentally, the optical module 20 may include reflection mirrors 22 other than those shown in FIG. 1.

The lenses 23 are disposed along the optical path between the first window 21A and the second window 21B, and impart predetermined optical characteristics to the pulse laser beam. The lenses 23 constitute a beam shaping optical system which shapes the pulse laser beam in a desired beam profile. For example, the pulse laser beam, which has passed through each lens 23, diverges, converges, or is collimated. The pulse laser beam, which has passed through the plural lenses 23, is shaped to have a desired beam profile, for example, a laterally elongated rectangular outer shape in a plane perpendicular to the direction of travel of the beam. Incidentally, the optical module 20 may include lenses 23 other than those shown in FIG. 1.

The lens holders 30 hold the lenses 23 and are fixed within the housing 21. Although a detailed description of the structure of the lens holders 30 is omitted, each lens holder 30 includes a mechanism for adjusting the position of the lens 23 that is held.

The laser device 10, anneal chamber 40 and optical module 20 are mounted on the platform frame 50. The platform frame 50 is constructed by assembling steel members in a grid pattern, or constructed of a plate member. This platform frame 50 is a single base with each side several meters long. The laser device 10 and anneal chamber 40 are fixed to the platform frame 50 by fixing members such as bolts. The housing 21 of the optical module 20 is fixed to the platform frame 50 by fixing members such as bolts, and a part of the housing 21 is supported by a frame (not shown) which is fixed to the platform frame 50.

The elastic body 60 is configured to lift the platform frame 50 from a building floor 70. Specifically, the elastic body 60 is interposed between the platform frame 50 and the building floor 70. Thus, the platform frame 50 is in contact with neither the building floor 70, needless to say, nor any part of the building. In short, the laser device 10, optical module 20 and anneal chamber 40 are fixed as an integral body on the single platform frame 50 in the state in which the laser device 10, optical module 20 and anneal chamber 40 are independent from the building.

In addition, as the elastic body 60, an elastic body is chosen which has such characteristics as to attenuate the vibration of the frequency of power, which is supplied to a building, to 1/10 or less. For example, the power supply frequency of eastern Japan is 50 Hz and the power supply frequency of western Japan is 60 Hz.

The elastic body 60 is, for instance, a rubber vibration isolator. Alternatively, the elastic body 60 may be an active damper, a passive damper, a spring member, an air cushion, or an air spring. In the meantime, when the rubber vibration isolator is used as the elastic body 60, the height of that part of the laser annealing device, which is lifted from the building floor 70, can be decreased, and reduction in cost and simple maintenance can be realized.

According to the laser annealing apparatus with the above-described structure, a process substrate SUB, on which an amorphous silicon thin film has been formed, is placed on the stage 41 of the anneal chamber 40, and the stage 41 is moved to adjust the position of the process substrate SUB. Thereafter, a pulse laser beam which is set at a relatively high output is emitted from the laser device 10.

The pulse laser beam, which has been emitted from the laser device 10, travels through the optical module 20, is guided to the anneal chamber 40, and is radiated on the process substrate SUB. Thereby, the amorphous silicon is crystal-grown into polysilicon. The process substrate SUB, on which the polysilicon has been formed, is patterned in accordance with the shape of a thin-film transistor which is to be provided in each of pixels. Then, using the process substrate SUB, an array substrate for a flat-panel display device, such as a liquid crystal display device, is fabricated.

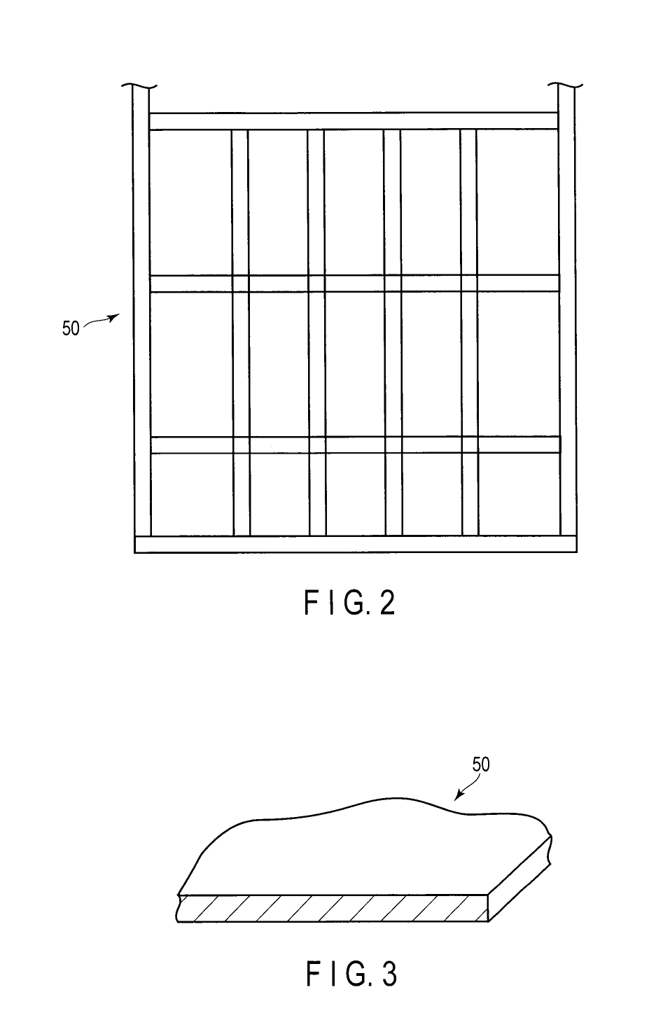

FIG. 2 schematically illustrates an example of the platform frame 50 which is applicable to the laser annealing apparatus shown in FIG. 1.

The platform frame 50 shown in FIG. 2 is constructed by assembling steel members in a grid pattern. FIG. 2 shows only a part of the platform frame 50, on which a partial unit (e.g. anneal chamber 40) is disposed. As such steel members, use may be made of steel members each having, for example, an H cross section or an I cross section. Although not illustrated, the elastic body 60 is disposed, for example, at each intersection part (joint part) of the steel members.

FIG. 3 schematically illustrates another example of the platform frame 50 which is applicable to the laser annealing apparatus shown in FIG. 1.

The platform frame 50 shown in FIG. 3 is constructed of a plate member.

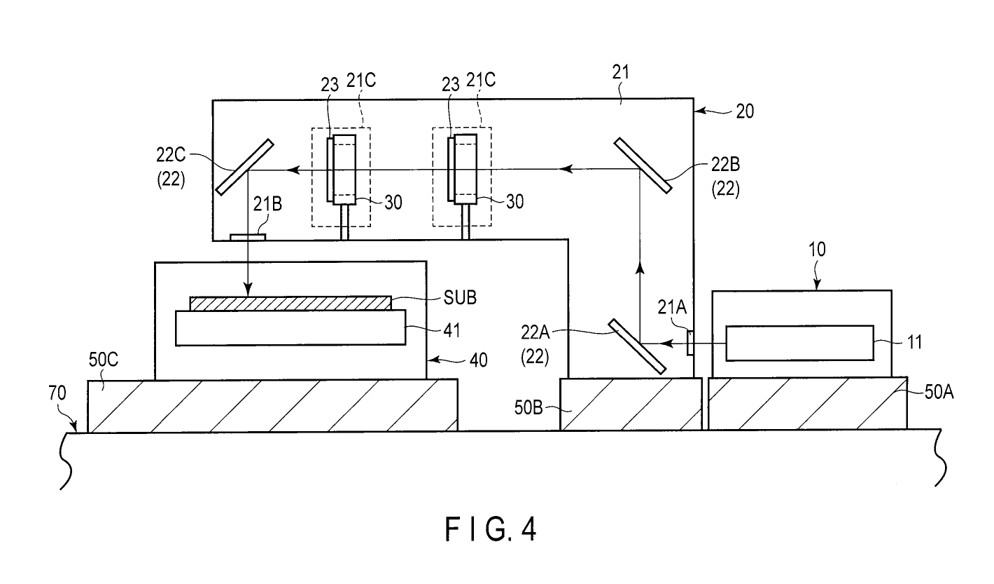

FIG. 4 schematically illustrates the structure of a laser annealing apparatus according to a comparative example. The same structural elements as those in FIG. 1 are denoted by like reference numerals, and a detailed description thereof is omitted.

The comparative example shown in FIG. 4 differs from the structure example of the embodiment shown in FIG. 1 in that the laser device 10, optical module 20 and anneal chamber 40 are individually mounted on frames 50A, 50B and 50C, respectively.

In this comparative example, vibrations from devices disposed in the building, such as an air-conditioner and a device disposed around the laser annealing apparatus, propagate from the building floor 70 to the frames 50A to 50C, respectively. Thus, the laser device 10, optical module 20 and anneal chamber 40 tend to vibrate independently. Such vibrations of the individual units cause a displacement of the optical axis of the pulse laser beam traveling from the laser device 10 to the anneal chamber 40 via the optical module 20, and cause variations of the radiation position of the pulse laser beam on the process substrate SUB, the shape of the beam, and the focal point of the beam. As a result, it becomes difficult to form desired polysilicon. If the vibrations of the individual units continue, a measure, such as stopping the radiation of the pulse laser beam onto the process substrate SUB, may become necessary.

On the other hand, according to the present embodiment, since the laser device 10, optical module 20 and anneal chamber 40 are mounted on the common platform frame 50, it is possible to suppress individual vibrations of the units, i.e. the laser device 10, optical module 20 and anneal chamber 40.

In addition, by the provision of the elastic body 60 which supports the platform frame 50, the platform frame 50 is held in the state in which the platform frame 50 is lifted from the building floor 70. Thus, it is possible to suppress the propagation of vibration to the platform frame 50 from devices disposed in the building, such as an air-conditioner and a device disposed around the laser annealing apparatus. Moreover, the elastic body 60 has such characteristics as to attenuate the vibration of the frequency of power, which is supplied to the building, to 1/10 or less. It is possible, therefore, to further suppress the propagation of vibration from the building floor 70 to the platform frame 50. Besides, a sturdy building is not necessary, and the degree of freedom is increased with respect to the location of installation of the laser annealing apparatus.

Thereby, it is possible to suppress a displacement of the optical axis of the pulse laser beam traveling from the laser device 10 to the anneal chamber 40 via the optical module 20, and to suppress variations of the radiation position of the pulse laser beam on the process substrate SUB, the shape of the beam, and the focal point of the beam. Thus, desired polysilicon can be formed. Therefore, a decrease in manufacturing yield can be suppressed.

As has been described above, according to the present embodiment, a laser annealing apparatus, which can suppress a decrease in manufacturing yield, can be provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A laser annealing apparatus comprising:
a laser device configured to emit a pulse laser beam;
an anneal chamber including a stage on which a process substrate, on which an amorphous silicon thin film is formed, is placed;
an optical module disposed between the laser device and the anneal chamber and configured to guide the pulse laser beam, which is emitted from the laser device, to the anneal chamber;
a platform frame on which the laser device, the anneal chamber and the optical module are mounted; and
an elastic body configured to lift the platform frame from a building floor.

2. The laser annealing apparatus of claim 1, wherein the elastic body has such characteristics as to attenuate a vibration of a frequency of power, which is supplied to a building, to 1/10 or less.

3. The laser annealing apparatus of claim 1, wherein the elastic body is a rubber vibration isolator.

4. The laser annealing apparatus of claim 1, wherein the platform frame is constructed by assembling steel members in a grid pattern.

5. The laser annealing apparatus of claim 1, wherein the platform frame is constructed of a plate member.
